(19) United States
(12) Patent Application Publication
(10) Pub. No.: US 2021/0351231 A1
(43) Pub. Date: Nov. 11, 2021

(54) LED DISPLAY APPARATUS, MASS TRANSFER METHOD, AND STORAGE MEDIUM

(71) Applicant: CHONGQING KONKA PHOTOELECTRIC TECHNOLOGY RESEARCH INSTITUTE CO., LTD., Chongqing (CN)

(72) Inventors: Pengyue ZHANG, Chongqing (CN); Ruilin XU, Chongqing (CN); Chia-Hua HUANG, Chongqing (CN)

(21) Appl. No.: 17/382,840

(22) Filed: Jul. 22, 2021

Related U.S. Application Data
(63) Continuation of application No. PCT/CN2020/117395, filed on Sep. 24, 2020.

(30) Foreign Application Priority Data
Apr. 7, 2020 (CN) 202010271742.3

(51) Int. Cl. H01L 27/15; H01L 33/00

(52) U.S. Cl. CPC H01L 27/156; H01L 2933/0016; H01L 33/0093

(57) ABSTRACT

The present application relates to the field of display manufacturing, and more particularly, to a light emitting diode (LED) display apparatus. The LED display apparatus includes a display backplane, first LED chips, second LED chips, and third LED chips. The display backplane is provided with first bosses and second bosses. The first LED chips are disposed on the first bosses, the second LED chips are disposed on the second bosses. The first bosses each have a height of H11 greater than a height H22 of the second bosses. The present application also relates to a mass transfer method and a storage medium.

### CROSS REFERENCE TO RELATED APPLICATION(S)

This application is a continuation of International Application No. PCT/CN2020/117395, filed on Sep. 24, 2020, which claims priority to Chinese Patent Application No. 202010271742.3, filed on Apr. 7, 2020, the disclosures of which are hereby incorporated by reference in their entireties.

### TECHNICAL FIELD

The present application relates to the technical field of manufacturing of a light emitting diode (LED) display apparatus, and more particularly, to an LED display apparatus, a mass transfer method, and a storage medium.

### BACKGROUND

The development of micro LED chips is one of the hot topics of display technologies in the future. However, there are many technical difficulties, and related technologies, especially the key mass transfer technologies are complex. With the development of the mass transfer technologies, there are many technical branches, such as electrostatic adsorption, laser burning, and so on.

At present, a mass transfer process is generally performed on three colors (i.e., red, blue, and green, RGB) of micro LED chips in stages. That is, only one color of micro LED chips are transferred at one time. Micro LED chips of a corresponding shape fall into loading grooves via vibration and wind. Therefore, for three colors (i.e., RGB) of micro LED chips with a same shape, a mass transfer process needs to be performed three times. The micro LED chips have a size below 100 um. Therefore, generally, in the mass transfer process, transfer heads are made for transfer and need to be very small to match the micro LED chips, so accuracy requirements and thus manufacturing requirements for a transfer device are high.

### SUMMARY

According to a first aspect, a light emitting diode (LED) display apparatus is provided. The LED display apparatus includes: a display backplane divided into multiple pixel areas in an array, each pixel area being provided with: a first LED chip; a second LED chip; a third LED chip; a first boss disposed on the display backplane; and a second boss disposed on the display backplane; where the first LED chip is disposed on the first boss, the second LED chip is disposed on the second boss, the third LED chip is disposed on the display backplane within the pixel area, and a height H11 of the first boss is greater than a height H22 of the second boss.

According to a second aspect, a non-transitory computer readable storage medium is provided. The non-transitory computer readable storage medium stores a computer program which, when executed by a processor, causes the processor to: provide a first growth substrate with first LED chips thereon, electrodes of the first LED chips facing away from the first growth substrate; provide a first temporary substrate with an adhesive thereon, adhere the electrodes of the first LED chips to a first adhesive layer of the first temporary substrate, and peel off the first growth substrate; coat, on the first temporary substrate with the first LED chips thereon, photosensitive resin to form a first photosensitive resin layer having a thickness of H1 greater than a height h1 of each of the first LED chips, i.e., H1>h1; cover, on the first photosensitive resin layer, a second temporary substrate made of a light-transmitting material; provide a patterned mask to block light towards first LED chips not to be transferred, and to expose a part of the first photosensitive resin layer corresponding to first LED chips to be transferred for solidification of the part of the first photosensitive resin layer, and remove an unexposed part of the first photosensitive resin layer with a developer, a remaining part of the first photosensitive resin layer serving as first transfer heads; peel off, selectively from the first adhesive layer by laser peeling, the first LED chips to be transferred, so that the first LED chips to be transferred are adhered to the second temporary substrate via the first transfer heads; and move the second temporary substrate to transfer the first LED chips on the second temporary substrate to a display backplane and dissolve the first transfer heads with a peeling liquid to separate the first LED chips from the second temporary substrate, to complete transfer of the first LED chips.

### BRIEF DESCRIPTION OF THE DRAWINGS

To illustrate the technical solutions in the embodiments of the present application or the related art more clearly, drawings used for description of the embodiments or the related art will be briefly introduced below. It is obvious that the drawings in the following description are only some implementations of the present application. Other drawings can be obtained by those of ordinary skill in the art based on these drawings without creative work.

FIG. 1 shows a structure of an LED display apparatus.

FIG. 2 is a flowchart of a method of embodiment 2.

FIG. 3 is a diagram of a state in which first LED chips are on a first growth substrate of embodiment 2.

FIG. 4 is a diagram of a state in which the first LED chips are transferred to a first temporary substrate of embodiment 2.

FIG. 5 is a diagram of a state in which a first photosensitive resin layer is formed of embodiment 2.

FIG. 6 is a diagram of a state after the first photosensitive resin layer is exposed and developed of embodiment 2.

FIG. 7 is a schematic diagram of separating the first LED chips form the first temporary substrate of embodiment 2.

FIG. 8 is a schematic diagram of transferring the first LED chips to a display backplane of embodiment 2.

FIG. 9 is a schematic diagram of a second growth substrate with second LED chips thereon.

FIG. 10 is a schematic diagram of transferring the second LED chips to a third temporary substrate.

FIG. 11 is a schematic diagram of forming a second photosensitive resin layer.

FIG. 12 is a schematic diagram of forming second transfer heads.

FIG. 13 is a schematic diagram of separating third LED chips to be transferred from a fourth temporary substrate.

FIG. 14 is a schematic diagram of transferring the second LED chips to the display backplane.

FIG. 15 is a schematic diagram of a third growth substrate with third LED chips thereon.

FIG. 16 is a schematic diagram of transferring the third LED chips to a fifth temporary substrate.

FIG. 17 is a schematic diagram of forming a third photosensitive resin layer on third LED chips.

FIG. 18 is a schematic diagram after third transfer heads are formed.

FIG. 19 is a schematic diagram of separating third LED chips to be transferred from a third adhesive layer.

FIG. 20 is a schematic diagram of transferring the third LED chips to a display backplane.

FIG. 21 is a flowchart of a method of embodiment 3.

FIG. 22 is a schematic diagram after the first LED chips are picked up according to the method of embodiment 2.

FIG. 23 is a schematic diagram of an initial state of second LED chips of embodiment 3.

FIG. 24 is a schematic diagram of forming a second photosensitive resin layer of embodiment 3.

FIG. 25 is a schematic diagram of a second temporary substrate covered on the second photosensitive resin layer.

FIG. 26 is a schematic diagram of a process of forming second transfer heads.

FIG. 27 is schematic diagram of separating the second LED chips from a third temporary substrate.

FIG. 28 is a schematic diagram of a growth substrate with third LED chips thereon.

FIG. 29 is a schematic diagram of a process of transferring the third LED chips to a fourth temporary substrate.

FIG. 30 is schematic structural diagram of a second temporary substrate covered on a third photosensitive resin layer.

FIG. 31 is a schematic diagram of a process of forming third transfer heads.

FIG. 32 is a schematic diagram of picking up the first LED chips, the second LED chips, and the third LED chips.

FIG. 33 is a schematic diagram of transferring the first LED chips, the second LED chips, and the third LED chips to a display backplane.

Description of reference numbers: first growth substrate 111, first temporary substrate 112, photosensitive resin layer 113, second temporary substrate 114/211, first transfer head 115/212, patterned mask 116, first LED chip 110/210, display backplane 100/200, second LED chip 120/220, third temporary substrate 121, second transfer head 1231/225, third LED chip 130/230, fourth temporary substrate 124/310, third transfer head 1331/323, first boss 140/241, second boss 150/242, second growth substrate 221, third temporary substrate 222, second adhesive layer 2221, second photosensitive resin layer 123/223, first groove 224, second groove 321, third groove 322, third adhesive layer 311, third photosensitive resin layer 133/320, fifth temporary substrate 132, and sixth temporary substrate 134.

### DETAILED DESCRIPTION

To make the purposes, technical solutions, and advantages of the present application clearer, the present application will be described in detail with reference to the accompanying drawings and embodiments. It should be understood that the specific embodiments described herein are only used to illustrate but not to limit the present application.

In the description of the present application, it should be understood that terms “center”, “longitudinal”, “transverse”, “length”, “width”, “thickness”, “upper”, “lower”, “front”, “back”, “left”, “right”, “vertical”, “horizontal”, “top”, “bottom”, “inner”, “outer”, “clockwise”, “counterclockwise”, and other indicated orientations or positional relationships are based on orientations or positional relationships shown in the drawings, and are only for the convenience of describing the present application and simplicity, but not to indicate or imply that an indicated apparatus or element must have a specific orientation, be constructed and operated in a specific orientation, and thus cannot be understood as a limit to the present application. In addition, terms “first” and “second” are only used for description, and cannot be understood as indicating or implying relative importance or implicitly indicating the number of indicated technical features. Therefore, a feature defined with “first” and “second” may explicitly or implicitly include one or more of the features. In the description of the present application, “multiple” means two or more than two, unless otherwise specifically defined.

In the description of the present application, it should be noted that, unless otherwise clearly specified and limited, terms “installation”, “connecting”, and “connection” should be understood in a broad sense. For example, it can be a fixed connection, a detachable connection, or an integral connection. It can be a mechanical connection or an electrical connection. It can be directly connected or indirectly connected through an intermediate medium. It can be an internal communication between two elements or an interaction relationship between two elements. For those of ordinary skill in the art, specific meanings of the above-mentioned terms in the present application can be understood according to specific circumstances.

In semiconductor packaging, polymers with high elasticity and ease of processing are usually used. These polymers can be solidified at room temperature after being spin-coated. Generally, after a mold is made, a polymer material is poured into the mold, and a transfer micropillar is formed after solidification. A micro-element can be picked up by alignment with the transfer micropillar. After the micro-element is transferred, the micropillar can be crushed by mechanical force. However, this process is complex. More importantly, the micropillar needs to be precisely aligned with the micro-element to pick it up. Product yield is easy to decline.

Based on the above, an LED display apparatus is designed in the present application. The mass transfer of micro LED chips can be well realized with the LED display apparatus. A specific structure of the LED display apparatus is as follows.

An LED display apparatus is provided. The LED display apparatus includes a display backplane. The display backplane is divided into multiple pixel areas in an array. Each pixel area is provided with a first LED chip, a second LED chip, a third LED chip, a first boss disposed on the display backplane, and a second boss disposed on the display backplane. The first LED chip is disposed on the first boss, the second LED chip is disposed on the second boss, the third LED chip is disposed on the display backplane within the pixel area, and a height H11 of the first boss is greater than a height H22 of the second boss.

In an embodiment, the second LED chip has a height of h2, the third LED chip has a height of h3, and the height H11 of the first boss and the height H22 of the second boss meet the following conditions: H22≥h3 and H11≥h2+h3.

A mass transfer method is provided. The mass transfer method includes the following. At S10, a first growth substrate with first LED chips thereon is provided, where electrodes of the first LED chips face away from the first growth substrate. At S11, a first temporary substrate with an adhesive thereon is provided, the electrodes of the first LED chips are adhered to a first adhesive layer of the first temporary substrate, and the first growth substrate is peeled off. At S12, photosensitive resin is coated on the first temporary substrate with the first LED chips thereon to form a first photosensitive resin layer having a thickness of H1 greater than a height h1 of each of the first LED chips, i.e., H1>h1. At S13, a second temporary substrate made of a light-transmitting material is covered on the first photosensitive resin layer. A patterned mask is provided to block light towards first LED chips not to be transferred, and to expose a part of the first photosensitive resin layer corresponding to first LED chips to be transferred for solidification of the part of the first photosensitive resin layer, and an unexposed part of the first photosensitive resin layer is removed with a developer, where a remaining part of the first photosensitive resin layer serves as first transfer heads. At S14, the first LED chips to be transferred are peeled off selectively from the first adhesive layer by laser peeling, so that the first LED chips to be transferred are adhered to the second temporary substrate via the first transfer heads. At S15, the second temporary substrate is moved to transfer the first LED chips on the second temporary substrate to a display backplane and the first transfer heads are dissolved with a peeling liquid to separate the first LED chips from the second temporary substrate, to complete transfer of the first LED chips.

In an embodiment, the method further includes the following. A second growth substrate with second LED chips thereon is provided, where electrodes of the second LED chips face away from the second growth substrate. A third temporary substrate with an adhesive thereon is provided, the electrodes of the second LED chips are adhered to a second adhesive layer of the third temporary substrate, and the second growth substrate is peeled off. Photosensitive resin is coated on the third temporary substrate with the second LED chips thereon to form a second photosensitive resin layer having a thickness of H2 greater than a height h2 of each of the second LED chips, i.e., H2>h2, where if the height h2 of each of the second LED chips is unequal to the height h1 of each of the first LED chips, the thickness H2 of the second photosensitive resin layer covering the second LED chips is preset to meet the following condition: H2−h2>|h2−h1|. A fourth temporary substrate made of a light-transmitting material is covered on the second photosensitive resin layer. A patterned mask is provided to block light towards second LED chips not to be transferred, and to expose a part of the second photosensitive resin layer corresponding to second LED chips to be transferred for solidification of the part of the second photosensitive resin layer, and an unexposed part of the second photosensitive resin layer is removed with a developer, where a remaining part of the second photosensitive resin layer serves as second transfer heads. The second LED chips to be transferred are peeled off selectively from the second adhesive layer by laser peeling, so that the second LED chips to be transferred are adhered to the fourth temporary substrate via the second transfer heads. The fourth temporary substrate is moved to transfer the second LED chips on the fourth temporary substrate to the display backplane and the second transfer heads are dissolved with a peeling liquid to separate the second LED chips from the fourth temporary substrate, to complete transfer of the second LED chips.

In an embodiment, the method further includes the following. A third growth substrate with third LED chips thereon is provided, where electrodes of the third LED chips face away from the third growth substrate. A fifth temporary substrate with an adhesive thereon is provided, the electrodes of the third LED chips are adhered to a third adhesive layer of the fifth temporary substrate, and the third growth substrate is peeled off. Photosensitive resin is coated on the fifth temporary substrate with the third LED chips thereon to form a third photosensitive resin layer having a thickness of H3 greater than a height h3 of each of the third LED chips, i.e., H3>h3, where if the height h3 of each of the third LED chips, the height h2 of each of the second LED chips, and the height h1 of each of the first LED chips are unequal to each other, the thickness H3 of the third photosensitive resin layer covering the third LED chips is preset to meet the following conditions: H3−h3>|h3−h1|, H3−h3>|h3−h2|. A sixth temporary substrate made of a light-transmitting material is covered on the third photosensitive resin layer. A patterned mask is provided to block light towards third LED chips not to be transferred, and to expose a part of the third photosensitive resin layer corresponding to third LED chips to be transferred for solidification of the part of the third photosensitive resin layer, and an unexposed part of the third photosensitive resin layer is removed with a developer, where a remaining part of the third photosensitive resin layer serves as third transfer heads. The third LED chips to be transferred are peeled off selectively from the third adhesive layer by laser peeling, so that the third LED chips to be transferred are adhered to the sixth temporary substrate via the third transfer heads. The sixth temporary substrate is moved to transfer the third LED chips on the sixth temporary substrate to the display backplane and the third transfer heads are dissolved with a peeling liquid to separate the third LED chips from the sixth temporary substrate, to complete transfer of the third LED chips.

In an embodiment, the method further includes the following after S14 and before S15. At S21, a second growth substrate with second LED chips thereon is provided, where the second LED chips each have a height of h2. At S22, a third temporary substrate with a second adhesive layer formed thereon is provided, the second LED chips are adhered to the third temporary substrate, the second growth substrate is removed, and photosensitive resin is coated on the third temporary substrate with the second LED chips thereon to form a second photosensitive resin layer having a thickness of H21 which meets H21≥H1. At S23, first grooves corresponding to the first LED chips are formed on the second photosensitive resin layer, and the second temporary substrate with the first LED chips thereon is covered on the second photosensitive resin layer. At S24, a patterned mask is provided to block light towards second LED chips not to be transferred, and to expose a part of the second photosensitive resin layer corresponding to second LED chips to be transferred for solidification of the part of the second photosensitive resin layer, and an unexposed part of the second photosensitive resin layer is removed with a developer, where a remaining part of the second photosensitive resin layer serves as second transfer heads. At S25, the second LED chips to be transferred are peeled off selectively from the second adhesive layer by laser peeling, so that the second LED chips to be transferred are adhered to the second temporary substrate via the second transfer heads.

In an embodiment, the method further includes the following after S25 and before S15. At S31, a third growth substrate with third LED chips thereon is provided, where the third LED chips each have a height of h3. At S32, a fourth temporary substrate with a third adhesive layer formed thereon is provided, the third LED chips are adhered to the fourth temporary substrate, the third growth substrate is removed, and photosensitive resin is coated on the fourth temporary substrate with the third LED chips thereon to form a third photosensitive resin layer having a thickness of H31 which meets H31≥H2+h3. At S33, second grooves and third grooves corresponding to the first LED chips and the second LED chips are formed on the third photosensitive resin layer, and the fourth temporary substrate with the first LED chips and the second LED chips thereon is covered on the third photosensitive resin layer. At S34, a patterned mask is provided to block light towards third LED chips not to be transferred, and to expose a part of the third photosensitive resin layer corresponding to third LED chips to be transferred for solidification of the part of the third photosensitive resin layer, and an unexposed part of the third photosensitive resin layer is removed with a developer, where a remaining part of the third photosensitive resin layer serves as third transfer heads. At S35, the third LED chips to be transferred are peeled off selectively from the third adhesive layer by laser peeling, so that the third LED chips to be transferred are adhered to the second temporary substrate via the third transfer heads.

In an embodiment, the display backplane includes first bosses and second bosses, the first LED chips on the second temporary substrate are bonded to the first bosses, and the second LED chips on the second temporary substrate are bonded to the second bosses.

In an embodiment, the first bosses each have a height of H11, the second bosses each have a height of H22, and the following conditions are met: H22≥h3, H11≥H22+h2, H11=H31−H1, and H22=H31−H21.

In an embodiment, the first grooves and the second grooves are formed by exposure and development or by etching.

The technical effect of the present application includes the following. In the structure of the LED display apparatus in the present application, the three different LED chips are placed at different heights, such that they can be picked up in stages with transfer heads and can be transferred at one time, thereby saving processes.

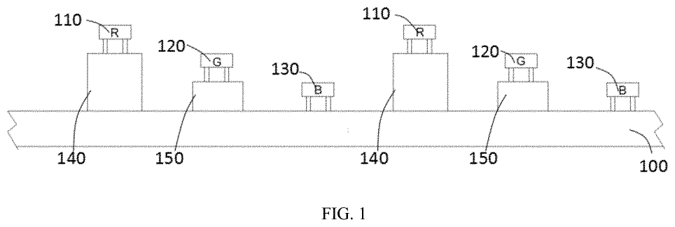

In embodiment 1, FIG. 1 shows a structure of an LED display apparatus according to the present application.

A structure of an LED display apparatus is provided. The LED display apparatus includes a display backplane 100 divided into multiple pixel areas in an array. Each pixel area is provided with a first LED chip 110, a second LED chip 120, and a third LED chip 130. First bosses 140 and second bosses 150 are formed on the display backplane 100. The first LED chip 110 is disposed on a first boss 140. The second LED chip 120 is disposed on a second boss 150. A height H11 of the first bosses 140 is greater than a height H22 of the second bosses 150.

A height of the second LED chip 120 is preset to be h2, a height of the third LED chip 130 is preset to be h3, H22≥h3, and H11≥h2+h3.

Correspondingly, electrodes corresponding to the first LED chips 110 are disposed on the first bosses 140 to be bonded to electrodes on the first LED chips 110, and electrodes corresponding to the second LED chips 120 are disposed on the second bosses 150 to be bonded to electrodes on the second LED chips 120. Third LED chips 130 are disposed on the display backplane 100 to be bonded to corresponding electrodes on the display backplane 100. In this way, the first LED chips 110, the second LED chips 120, and the third LED chips 130 are electrically connected with the display backplane 100.

Bosses of different heights can be disposed to place LED chips, so that the first LED chips 110, the second LED chips 120, and the third LED chips 130 can be picked up with transfer heads of different heights respectively, and then can be transferred to the display backplane 100 at one time. In this way, there is no need to separately transfer each type of LED chips, thereby simplifying processes.

In this embodiment, the first LED chips 110 are red chips, the second LED chips 120 are green chips, and the third LED chips are blue chips. It can be understood that types of LED chips are interchangeable and can also include other types of chips.

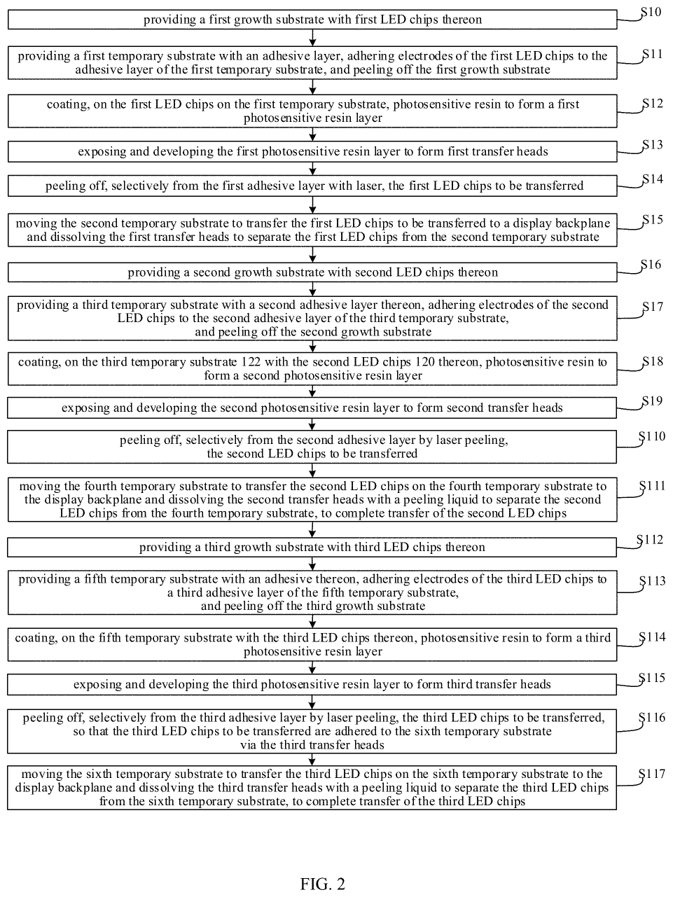

In embodiment 2, FIGS. 2-9 show a mass transfer method of the present application, and FIG. 2 is a flow chart of a method of this embodiment. The method includes the following.

At S10, a first growth substrate 111 with first LED chips 110 thereon is provided.

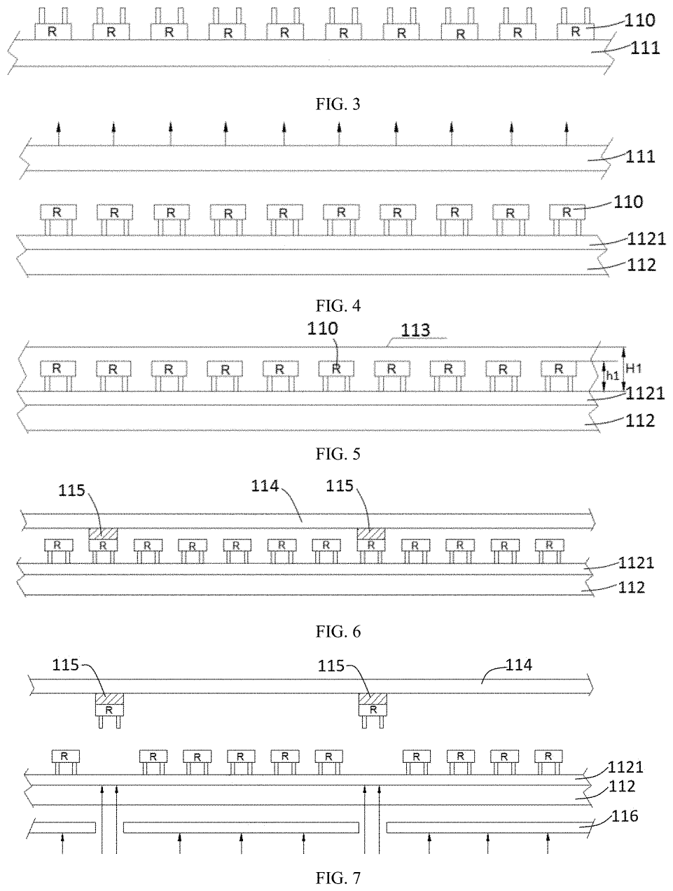

Referring to FIG. 3, electrodes of the first LED chips 110 face away from the first growth substrate 111. The first LED chips 110 can be micro LED chips in a red-light band or other types of micro LED chips, which depends on requirements.

At S11, a first temporary substrate 112 with an adhesive layer 1121 thereon is provided, the electrodes of the first LED chips 110 are adhered to the adhesive layer 1121 of the first temporary substrate 112, and the first growth substrate 111 is peeled off.

Referring to FIG. 4, the first growth substrate 111 is peeled off by laser peeling. The first growth substrate is irradiated with light of a specific wavelength, so that there is no adhesion between the first LED chips 110 and the first growth substrate 111. In this way, the first LED chips 110 are transferred to the first temporary substrate 112.

At S12, photosensitive resin is coated on the first temporary substrate 112 with the first LED chips 110 thereon to form a first photosensitive resin layer 113.

Referring to FIG. 5, the first photosensitive resin layer 113 has a thickness of H1. The first LED chips 110 each have a height of h1. The following condition needs to be met: H1>h1, so that the first photosensitive resin layer can completely cover the first LED chips 110. Resin in the first photosensitive resin layer 113 is solidified by photosensitivity, that is, solidified after being irradiated with light of a specific wavelength, and can be dissolved with a specific chemical solvent after solidification, which is different from a chemical solvent used to dissolve unsolidified photosensitive resin.

At S13, first transfer heads 115 are formed after the first photosensitive resin layer 113 is exposed and developed.

Referring to FIG. 6, a second temporary substrate 114 is covered on the first photosensitive resin layer 113. A patterned mask (not shown) is provided to block light directed above first LED chips 110 not to be transferred, and to expose a part of the first photosensitive resin layer 113 that is not blocked from light for solidification of the part of the first photosensitive resin layer 113. An unexposed part of the first photosensitive resin layer 113 is removed by being dissolved with a developer to obtain the first transfer heads 115, and the first transfer heads 115 are connected with the first LED chips 110 to be transferred.

The second temporary substrate 114 is made of a light-transmitting material, so it can transmit light and make the exposure smoothly. An example light-transmitting material is quartz glass.

At S14, the first LED chips 110 to be transferred are peeled off selectively from the first adhesive layer 1121 with laser, so that the first LED chips 110 to be transferred are adhered to the second temporary substrate 114 via the first transfer heads 115.

Referring to FIG. 7, the first temporary substrate is made of a light-transmitting material. A patterned mask 116 is provided to block part of light so that light can only reach an area corresponding to the first LED chips 110 to be transferred. The first adhesive layer 1121 is made of a photosensitive material which loses its adhesion after being irradiated by a laser, so that the first LED chips 110 are smoothly separated from the first temporary substrate 112.

At S15, the second temporary substrate 114 is moved to transfer the first LED chips 110 to the display backplane 100, and the first transfer heads 115 are removed, so that the first LED chips 110 are separated from the second temporary substrate 114 and a transfer of the first LED chips 110 is completed.

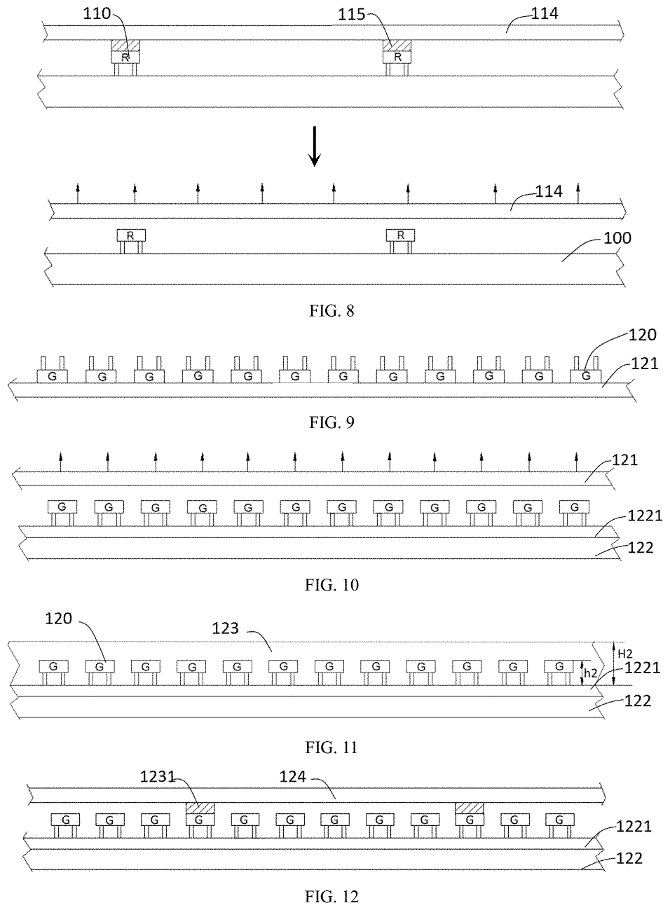

Referring to FIG. 8, the first transfer heads 115 can be dissolved with a specific peeling liquid, and then the first LED chips 110 are separated from the second temporary substrate 114. The electrodes of the first LED chips 110 can be bonded to electrodes on the display backplane 100 by heating, and then the first LED chips 110 are fixed on the display backplane 100. In this way, the transfer of the first LED chips is completed.

At S16, a second growth substrate 121 with second LED chips 120 thereon is provided. Referring to FIG. 9, electrodes of the second LED chips 120 face away from the second growth substrate.

At S17, a third temporary substrate 122 with a second adhesive layer 1221 thereon is provided. The electrodes of the second LED chips 120 are adhered to the second adhesive layer 1221 of the third temporary substrate 122, and the second growth substrate 121 is peeled off, which can refer to FIG. 10. In this embodiment, the second adhesive layer 1221 is made of photosensitive adhesive which loses its adhesion after being irradiated by light with a specific wavelength, thereby facilitating a peeling of chips.

At S18, photosensitive resin is coated on the third temporary substrate 122 with the second LED chips 120 thereon to form a second photosensitive resin layer 123 having a thickness of H2 greater than a height h2 of each of the second LED chips 120, i.e., H2>h2, where if the height h2 of each of the second LED chips 120 is unequal to the height h1 of each of the first LED chips 110, the thickness H2 of the second photosensitive resin layer 123 covering the second LED chips 120 is preset to meet the following condition: H2-h2>|h2−h1|, which can refer to FIG. 11.

At S19, second transfer heads 1231 are formed after the second photosensitive resin layer 123 is exposed and developed.

A fourth temporary substrate 124 made of a light-transmitting material is covered on the second photosensitive resin layer 123. A patterned mask is provided to block light towards second LED chips 120 not to be transferred, and to expose a part of the second photosensitive resin layer 123 corresponding to second LED chips 120 to be transferred for solidification of the part of the second photosensitive resin layer 123, and an unexposed part of the second photosensitive resin layer 123 is removed with a developer, where a remaining part of the second photosensitive resin layer 123 serves as the second transfer heads 1231, which can refer to FIG. 12.

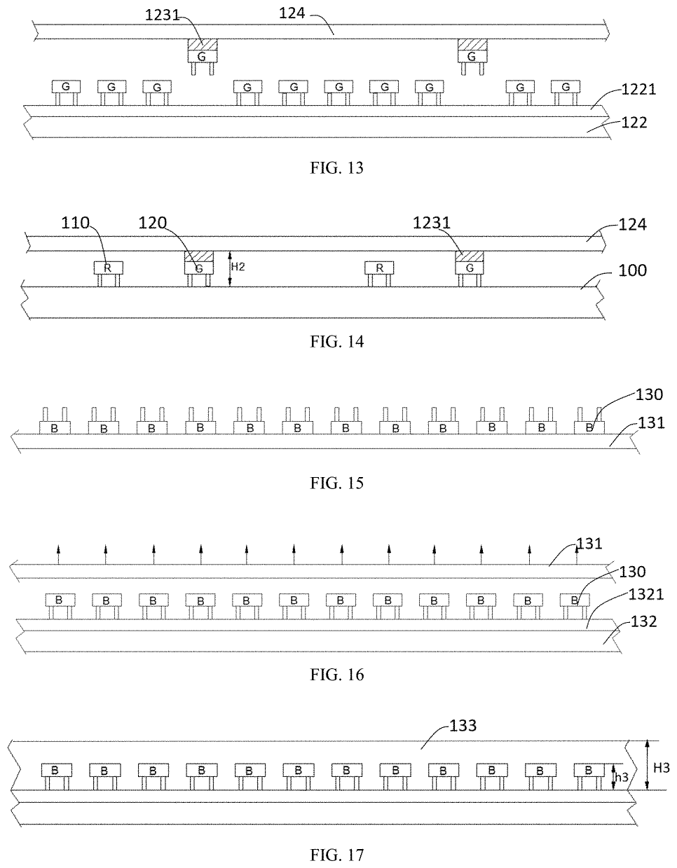

At S110, the second LED chips 120 to be transferred are peeled off selectively from the second adhesive layer 1221 by laser peeling, so that the second LED chips 120 to be transferred are adhered to the fourth temporary substrate 124 via the second transfer heads 1231, which can refer to FIG. 13.

At S111, the fourth temporary substrate 124 is moved to transfer the second LED chips on the fourth temporary substrate 124 to the display backplane 100 and the second transfer heads 1231 are dissolved with a peeling liquid to separate the second LED chips from the fourth temporary substrate 124, to complete transfer of the second LED chips 120, which can refer to FIG. 14.

At S112, a third growth substrate 131 with third LED chips 130 thereon is provided, where electrodes of the third LED chips 130 face away from the third growth substrate 131, which can refer to FIG. 15.

At S113, a fifth temporary substrate 132 with an adhesive thereon is provided, the electrodes of the third LED chips 130 are adhered to a third adhesive layer 1321 of the fifth temporary substrate 132, and the third growth substrate 131 is peeled off, which can refer to FIG. 16. In this embodiment, the adhesive is photosensitive adhesive which loses its adhesion after being irradiated by light with a specific wavelength, thereby facilitating a peeling of chips.

At S114, photosensitive resin is coated on the fifth temporary substrate 132 with the third LED chips 130 thereon to form a third photosensitive resin layer 133.

The third photosensitive resin layer 133 has a thickness of H3 greater than a height h3 of each of the third LED chips 130, i.e., H3>h3, where if the height h3 of each of the third LED chips 130, the height h2 of each of the second LED chips 120, and the height h1 of each of the first LED chips 110 are unequal to each other, the thickness H3 of the third photosensitive resin layer 133 covering the third LED chips 130 is preset to meet the following conditions: H3−h3>⊕h3−h1| and H3−h3>|h3−h2|, which can refer to FIG. 17. These conditions need to be met, so that when the third LED chips 130 are transferred to the display backplane 100, they will not collide with the first LED chips 110 and the second LED chips 120 transferred.

At S115, third transfer heads 1331 are formed after the third photosensitive resin layer 133 is exposed and developed.

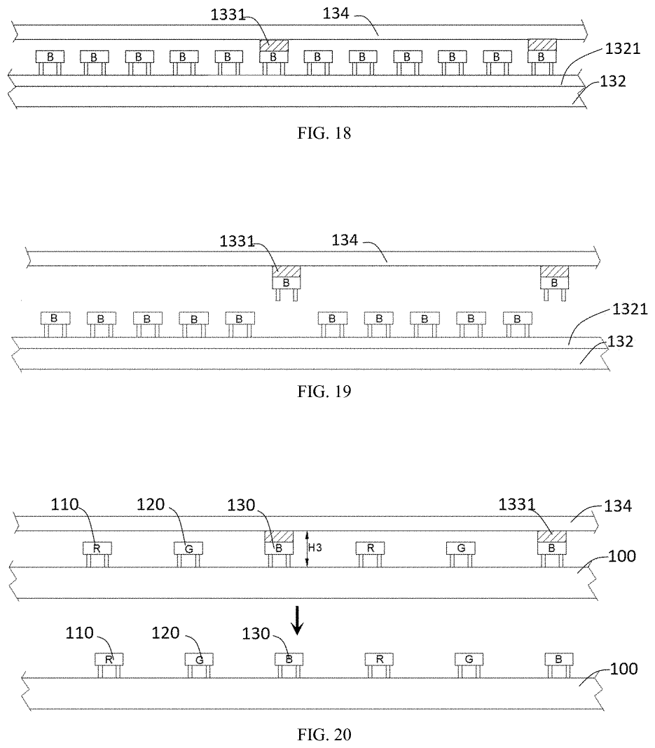

A sixth temporary substrate 134 made of a light-transmitting material is covered on the third photosensitive resin layer 133. A patterned mask is provided to block light towards third LED chips 130 not to be transferred, and to expose a part of the third photosensitive resin layer 133 corresponding to third LED chips 130 to be transferred for solidification of the part of the third photosensitive resin layer 133, and an unexposed part of the third photosensitive resin layer 133 is removed with a developer, where a remaining part of the third photosensitive resin layer 133 serves as third transfer heads 1331, which can refer to FIG. 18.

At S116, the third LED chips 130 to be transferred are peeled off selectively from the third adhesive layer 1321 by laser peeling, so that the third LED chips 130 to be transferred are adhered to the sixth temporary substrate 134 via the third transfer heads 1331, which can refer to FIG. 19. For example, a patterned mask is provided to block light towards third LED chips 130 not to be transferred, so that only third LED chips 130 to be transferred are peeled off from the third adhesive layer 1321.

At S117, the sixth temporary substrate 134 is moved to transfer the third LED chips 130 on the sixth temporary substrate 134 to the display backplane 100 and the third transfer heads 1331 are dissolved with a peeling liquid to separate the third LED chips 130 from the sixth temporary substrate 134, to complete transfer of the third LED chips 130, which can refer to FIG. 20. When the third transfer heads 1331 are dissolved with the peeling liquid, no mechanical stress will be applied, so that chips will not be affected, which is also one of the advantages of the present application.

At present, there are generally three types of LED chips according to their wavebands, namely, red-light-band LED chips, green-light-band LED chips, and blue-light-band LED chips. In this embodiment, the first LED chips 110 are red-light-band LED chips, the second LED chips 120 are green-light-band LED chips, and the third LED chips 130 are blue-light-band LED chips. In another example, a combination of other different types of LED chips is possible, which is not limited to this embodiment.

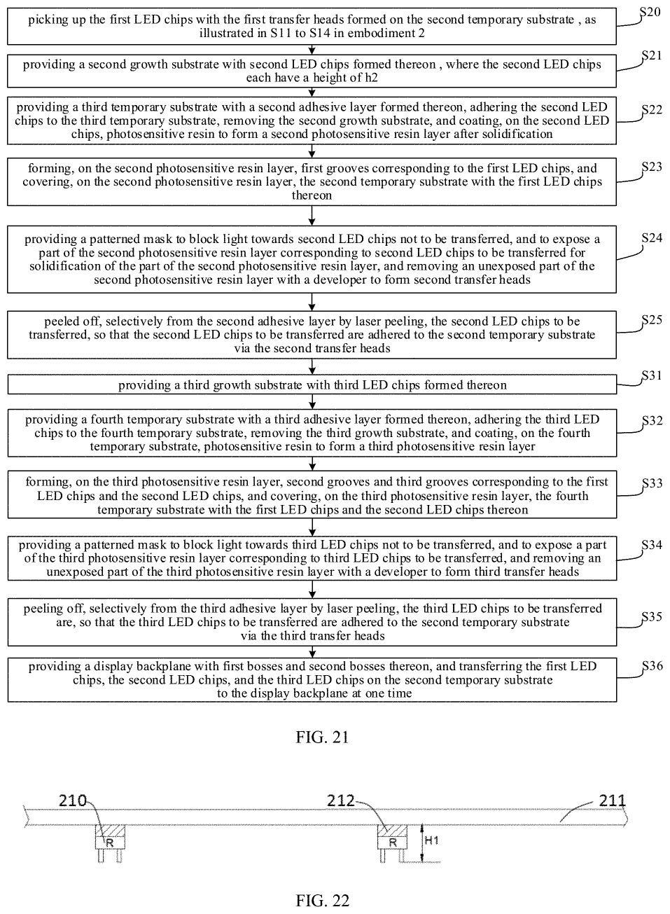

In embodiment 3, FIGS. 21-33 shows a mass transfer method of the present application, where FIG. 21 is a flow chart of a method of this embodiment. The method includes the following.

At S20, the first LED chips 210 are picked up with the first transfer heads 212 formed on the second temporary substrate 211, as illustrated in S11 to S14 in embodiment 2.

Referring to FIG. 22, the first LED chips 210 are adhered to the first transfer heads 212, and the first transfer heads 212 correspond to the first LED chips 210 in position and number. The first transfer heads 212 are formed by photosensitive resin solidified after exposure and development.

At S21, a second growth substrate 221 with second LED chips 220 formed thereon is provided, where the second LED chips each have a height of h2.

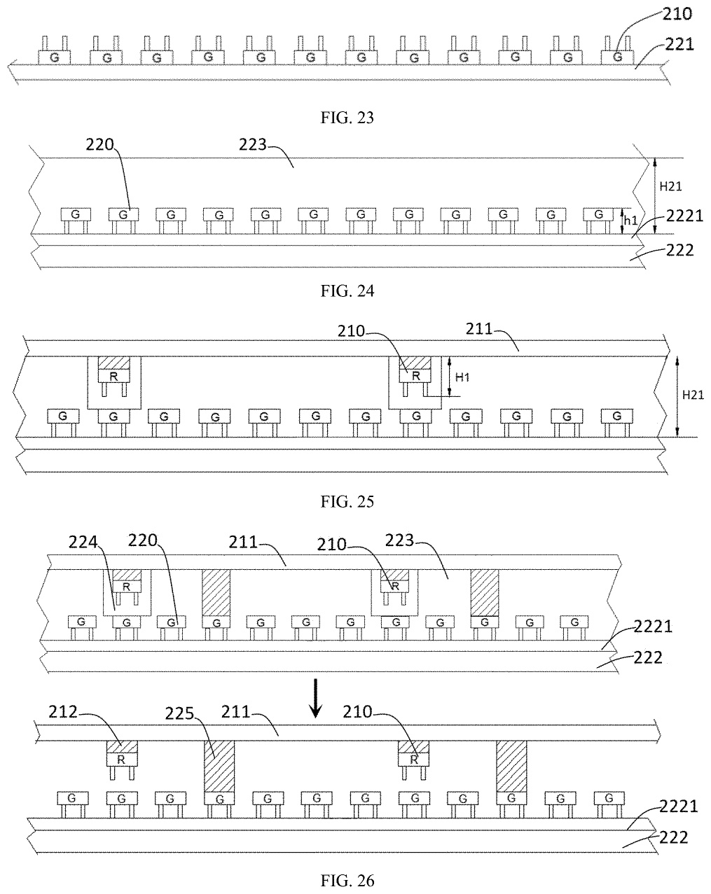

Referring to FIG. 23, electrodes of the second LED chips 220 face away from one side of the second growth substrate 221, and this state shows a structure after the second LED chips 210 are fabricated.

At S22, a third temporary substrate 222 with a second adhesive layer 2221 formed thereon is provided, the second LED chips 220 are adhered to the third temporary substrate 222, the second growth substrate 221 is removed, and photosensitive resin is coated on the second LED chips 220 to form a second photosensitive resin layer 223 after solidification.

Referring to FIG. 24, the second growth substrate 221 can be removed by laser irradiation. There will be no adhesion between the second growth substrate 221 and the second LED chips 220 after the second growth substrate 221 is irradiated by a laser, so that the second LED chips 220 are separated from the second growth substrate 221. After liquid photosensitive resin is coated on the second LED chips 220, the photosensitive resin flows and covers all the second LED chips 220. After solidification, the second photosensitive resin layer 223 is formed. The second photosensitive resin layer 223 has a thickness of H21, and the following condition needs to be met: H21≥H1.

At S23, first grooves 224 corresponding to the first LED chips 210 are formed on the second photosensitive resin layer 223, and the second temporary substrate 221 with the first LED chips 210 thereon is covered on the second photosensitive resin layer 223.

Referring to FIG. 25, the first grooves 224 corresponding to the first LED chips 210 are formed on the second photosensitive resin layer 223, and the second temporary substrate 211 with the first LED chips 210 thereon is covered on the second photosensitive resin layer 223. The first LED chips 210 on the second temporary substrate 211 correspond to the first grooves 224 in position. The first grooves 224 can be formed by removing a part of the photosensitive resin by exposure and development or by etching.

At S24, a patterned mask is provided to block light towards second LED chips 220 not to be transferred, and to expose a part of the second photosensitive resin layer 223 corresponding to second LED chips 220 to be transferred for solidification of the part of the second photosensitive resin layer 223, and an unexposed part of the second photosensitive resin layer 223 is removed with a developer, where a remaining part of the second photosensitive resin layer 223 serves as second transfer heads 225.

Referring to FIG. 26, the second temporary substrate 211 is made of a light-transmitting material which can transmit light. A patterned mask (not shown) is provided to cover the second temporary substrate 211 so that light only reaches a part of the second photosensitive resin layer 223 during exposure. The part of the second photosensitive resin layer 223 exposed is solidified to form the second transfer heads 225 connected with the second temporary substrate 211 and the second LED chips 220. Then, an unsolidified part of the second photosensitive resin layer 223 is dissolved by a developer and removed. The second transfer heads 225 are connected with the second LED chips 220.

At S25, the second LED chips 220 to be transferred are peeled off selectively from the second adhesive layer by laser peeling, so that the second LED chips 220 to be transferred are adhered to the second temporary substrate 211 via the second transfer heads 225.

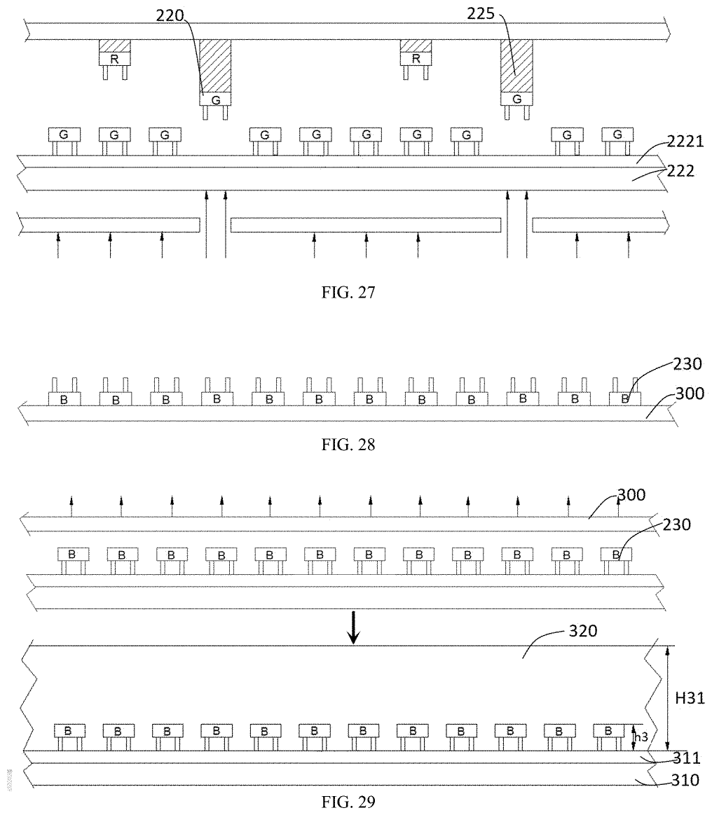

Referring to FIG. 27, the second adhesive layer is made of a photosensitive material which loses its adhesion after being irradiated with light of a specific wavelength. A patterned mask can be used to block light towards the second LED chips 220 not to be removed, so that light only reaches the second LED chips 220 to be removed. In this way, the second LED chips 220 to be removed are separated from the third temporary substrate 222.

At S31, a third growth substrate 300 with third LED chips 230 formed thereon is provided, where the third LED chips 230 each have a height of h3, which can refer to FIG. 28.

At S32, a fourth temporary substrate 310 with a third adhesive layer 311 formed thereon is provided, the third LED chips 230 are adhered to the fourth temporary substrate, the third growth substrate 310 is removed, and photosensitive resin is coated on the fourth temporary substrate 310 with the third LED chips 230 thereon to form a third photosensitive resin layer 320 having a thickness of H31 which meets H31≥H2+h3, which can refer to FIG. 29.

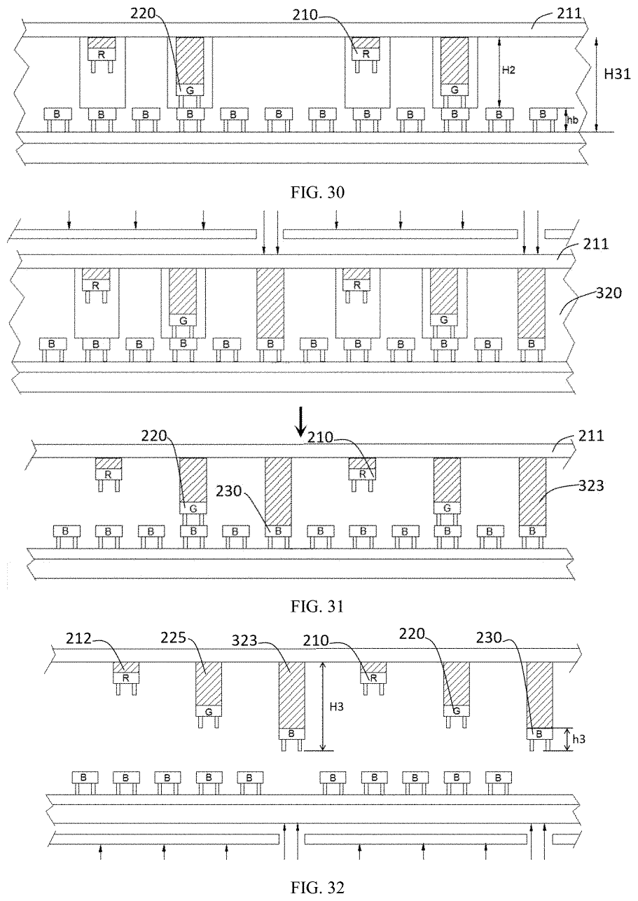

At S33, second grooves 321 and third grooves 322 corresponding to the first LED chips 210 and the second LED chips 220 are formed on the third photosensitive resin layer 320, and the fourth temporary substrate 310 with the first LED chips 210 and the second LED chips 220 thereon is covered on the third photosensitive resin layer 320, which can refer to FIG. 30.

At S34, a patterned mask is provided to block light towards third LED chips 230 not to be transferred, and to expose a part of the third photosensitive resin layer 320 corresponding to third LED chips 230 to be transferred for solidification of the part of the third photosensitive resin layer 320, and an unexposed part of the third photosensitive resin layer 320 is removed with a developer, where a remaining part of the third photosensitive resin layer 320 serves as third transfer heads 323, which can refer to FIG. 31.

At S35, the third LED chips 230 to be transferred are peeled off selectively from the third adhesive layer 311 by laser peeling, so that the third LED chips 230 to be transferred are adhered to the second temporary substrate 211 via the third transfer heads 323.

Referring to FIG. 32, the third transfer heads 323 are formed on the second temporary substrate 211, and the third transfer heads 323 are connected with the third LED chips 230.

The height of the third LED chips 310 is preset to be h3, and the thickness of the third photosensitive resin layer 320 formed in a process of manufacturing the third transfer heads 323 is H3, then H3>H2>H1.

At S36, a display backplane 200 with first bosses 241 and second bosses 242 thereon is provided, and the first LED chips 210, the second LED chips 220, and the third LED chips 230 on the second temporary substrate 211 are transferred to the display backplane 200 at one time.

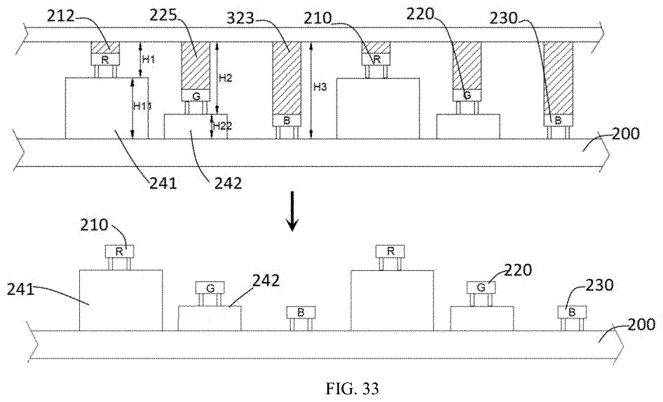

Referring to FIG. 33, the first LED chips 210 correspond to the first bosses 241 in position, and the second LED chips 220 correspond to the second bosses 242 in position, and then the second temporary substrate 211 is removed. If the first bosses each have a height of H11 and the second bosses each have a height of H22, the following height relationships need to be met: H22≥h3, H11≥H22+h2, H11=H31−H1, and H22=H31−H21, so that during a transfer process, the various types of LED chips will not collide with other structures and the transfer process will be smooth.

The second temporary substrate 211 is made of a light-transmitting material. The first LED chips 210, the second LED chips 220, and the third LED chips 230 can be separated from the second temporary substrate 211 by laser irradiation. The electrodes of the first LED chips 210, the second LED chips 220, and the third LED chip 230 are respectively heated and bonded to the electrodes on the first bosses 241, the second bosses 242, and the display backplane 200. In this way, the first LED chips 210, the second LED chips 220, and the third LED chip 230 are respectively fixedly connected with the first bosses 241, the second bosses 242, and the display backplane 200.

The three types of LED chips described in the present application are three colors (i.e., RGB) of LED chips according to actual applications, and their transfer sequence is not limited, and is not limited to this embodiment.

The mass transfer method described in the present application can transfer LED chips with high efficiency and high accuracy without manufacturing transfer heads.

The present application further provides a non-transitory computer readable storage medium. The non-transitory computer readable storage medium stores a computer program. When executed by a processor, the computer program causes the processor to perform the steps or operations described herein.

The above descriptions are only some embodiments of the present application, and are not intended to limit the present application. Any modifications, equivalent replacements, improvements, etc. made within the spirit and principle of the present application should fall into the scope of the present application.

In descriptions of this specification, descriptions with reference to terms “one embodiment”, “some embodiments”, “exemplary embodiments”, “examples”, “specific examples”, or “some examples”, etc. mean that specific features, structures, materials, or characteristics described in combination with embodiments or examples are included in at least one embodiment or example of the present application. In this specification, a schematic representation of above-mentioned terms does not necessarily refer to the same embodiment or example. Moreover, specific features, structures, materials, or characteristics described can be combined in an appropriate manner in any one or more embodiments or examples.

The above descriptions are only some embodiments of the present application, and are not intended to limit the present application. Any modifications, equivalent replacements, and improvements made within the spirit and principle of the present application should fall into the scope of the present application.

What is claimed is:

1. A light emitting diode (LED) display apparatus, comprising:
a display backplane divided into a plurality of pixel areas in an array, each pixel area being provided with:
a first LED chip;
a second LED chip;
a third LED chip;
a first boss disposed on the display backplane; and
a second boss disposed on the display backplane; wherein
the first LED chip is disposed on the first boss, the second LED chip is disposed on the second boss, the third LED chip is disposed on the display backplane within the pixel area, and a height H11 of the first boss is greater than a height H22 of the second boss.

2. The apparatus of claim 1, wherein the second LED chip has a height of h2, the third LED chip has a height of h3, and the height H11 of the first boss and the height H22 of the second boss meet the following conditions: H22≥h3 and H11≥h2+h3.

3. A mass transfer method, comprising:
providing a first growth substrate with first LED chips thereon, electrodes of the first LED chips facing away from the first growth substrate;
providing a first temporary substrate with an adhesive thereon, adhering the electrodes of the first LED chips to a first adhesive layer of the first temporary substrate, and peeling off the first growth substrate;
coating, on the first temporary substrate with the first LED chips thereon, photosensitive resin to form a first photosensitive resin layer having a thickness of H1 greater than a height h1 of each of the first LED chips, i.e., H1>h1;
covering, on the first photosensitive resin layer, a second temporary substrate made of a light-transmitting material;
providing a patterned mask to block light towards first LED chips not to be transferred, and to expose a part of the first photosensitive resin layer corresponding to first LED chips to be transferred for solidification of the part of the first photosensitive resin layer, and removing an unexposed part of the first photosensitive resin layer with a developer, a remaining part of the first photosensitive resin layer serving as first transfer heads;
peeling off, selectively from the first adhesive layer by laser peeling, the first LED chips to be transferred, so that the first LED chips to be transferred are adhered to the second temporary substrate via the first transfer heads; and
moving the second temporary substrate to transfer the first LED chips on the second temporary substrate to a display backplane and dissolving the first transfer heads with a peeling liquid to separate the first LED chips from the second temporary substrate, to complete transfer of the first LED chips.

4. The method of claim 3, further comprising:
providing a second growth substrate with second LED chips thereon, electrodes of the second LED chips facing away from the second growth substrate;
providing a third temporary substrate with an adhesive thereon, adhering the electrodes of the second LED chips to a second adhesive layer of the third temporary substrate, and peeling off the second growth substrate;
coating, on the third temporary substrate with the second LED chips thereon, photosensitive resin to form a second photosensitive resin layer having a thickness of H2 greater than a height h2 of each of the second LED chips, i.e., H2>h2, wherein if the height h2 of each of the second LED chips is unequal to the height h1 of each of the first LED chips, the thickness H2 of the second photosensitive resin layer covering the second LED chips is preset to meet the following condition: H2−h2>|h2−h1|;
covering, on the second photosensitive resin layer, a fourth temporary substrate made of a light-transmitting material;
providing a patterned mask to block light towards second LED chips not to be transferred, and to expose a part of the second photosensitive resin layer corresponding to second LED chips to be transferred for solidification of the part of the second photosensitive resin layer, and removing an unexposed part of the second photosensitive resin layer with a developer, a remaining part of the second photosensitive resin layer serving as second transfer heads;
peeling off, selectively from the second adhesive layer by laser peeling, the second LED chips to be transferred, so that the second LED chips to be transferred are adhered to the fourth temporary substrate via the second transfer heads; and
moving the fourth temporary substrate to transfer the second LED chips on the fourth temporary substrate to the display backplane and dissolving the second transfer heads with a peeling liquid to separate the second LED chips from the fourth temporary substrate, to complete transfer of the second LED chips.

5. The method of claim 4, further comprising:
providing a third growth substrate with third LED chips thereon, electrodes of the third LED chips facing away from the third growth substrate;
providing a fifth temporary substrate with an adhesive thereon, adhering the electrodes of the third LED chips to a third adhesive layer of the fifth temporary substrate, and peeling off the third growth substrate;
coating, on the fifth temporary substrate with the third LED chips thereon, photosensitive resin to form a third photosensitive resin layer having a thickness of H3 greater than a height h3 of each of the third LED chips, i.e., H3>h3, wherein if the height h3 of each of the third LED chips, the height h2 of each of the second LED chips, and the height h1 of each of the first LED chips are unequal to each other, the thickness H3 of the third photosensitive resin layer covering the third LED chips is preset to meet the following conditions: H3−h3>|h3−h1| and H3−h3>|h3−h2|;
covering, on the third photosensitive resin layer, a sixth temporary substrate made of a light-transmitting material;
providing a patterned mask to block light towards third LED chips not to be transferred, and to expose a part of the third photosensitive resin layer corresponding to third LED chips to be transferred for solidification of the part of the third photosensitive resin layer, and removing an unexposed part of the third photosensitive resin layer with a developer, a remaining part of the third photosensitive resin layer serving as third transfer heads;
peeling off, selectively from the third adhesive layer by laser peeling, the third LED chips to be transferred, so that the third LED chips to be transferred are adhered to the sixth temporary substrate via the third transfer heads; and
moving the sixth temporary substrate to transfer the third LED chips on the sixth temporary substrate to the display backplane and dissolving the third transfer heads with a peeling liquid to separate the third LED chips from the sixth temporary substrate, to complete transfer of the third LED chips.

6. The method of claim 3, further comprising:
after the first LED chips to be transferred are adhered to the second temporary substrate via the first transfer heads and before moving the second temporary substrate to transfer the first LED chips on the second temporary substrate to the display backplane and dissolving the first transfer heads with the peeling liquid to separate the first LED chips from the second temporary substrate, to complete transfer of the first LED chips,
providing a second growth substrate with second LED chips thereon, the second LED chips each having a height of h2;
providing a third temporary substrate with a second adhesive layer formed thereon, adhering the second LED chips to the third temporary substrate, removing the second growth substrate, and coating, on the third temporary substrate with the second LED chips thereon, photosensitive resin to form a second photosensitive resin layer having a thickness of H21 which meets H21≥H1;
forming, on the second photosensitive resin layer, first grooves corresponding to the first LED chips, and covering, on the second photosensitive resin layer, the second temporary substrate with the first LED chips thereon;
providing a patterned mask to block light towards second LED chips not to be transferred, and to expose a part of the second photosensitive resin layer corresponding to second LED chips to be transferred for solidification of the part of the second photosensitive resin layer, and removing an unexposed part of the second photosensitive resin layer with a developer, a remaining part of the second photosensitive resin layer serving as second transfer heads; and
peeling off, selectively from the second adhesive layer by laser peeling, the second LED chips to be transferred, so that the second LED chips to be transferred are adhered to the second temporary substrate via the second transfer heads.

7. The method of claim 6, further comprising:
after the second LED chips to be transferred are adhered to the second temporary substrate via the second transfer heads and before moving the second temporary substrate to transfer the first LED chips and the second LED chips on the second temporary substrate to the display backplane and dissolving the first transfer heads and the second transfer heads with the peeling liquid to separate the first LED chips and the second LED chips from the second temporary substrate, to complete transfer of the first LED and the second chips,
providing a third growth substrate with third LED chips thereon, the third LED chips each having a height of h3;
providing a fourth temporary substrate with a third adhesive layer formed thereon, adhering the third LED chips to the fourth temporary substrate, removing the third growth substrate, and coating, on the fourth temporary substrate with the third LED chips thereon, photosensitive resin to form a third photosensitive resin layer having a thickness of H31 which meets H31≥H2+h3;
forming, on the third photosensitive resin layer, second grooves and third grooves corresponding to the first LED chips and the second LED chips, and covering, on the third photosensitive resin layer, the fourth temporary substrate with the first LED chips and the second LED chips thereon;
providing a patterned mask to block light towards third LED chips not to be transferred, and to expose a part of the third photosensitive resin layer corresponding to third LED chips to be transferred for solidification of the part of the third photosensitive resin layer, and removing an unexposed part of the third photosensitive resin layer with a developer, a remaining part of the third photosensitive resin layer serving as third transfer heads; and
peeling off, selectively from the third adhesive layer by laser peeling, the third LED chips to be transferred, so that the third LED chips to be transferred are adhered to the second temporary substrate via the third transfer heads.

8. The method of claim 7, wherein the display backplane comprises first bosses and second bosses, the first LED chips on the second temporary substrate are bonded to the first bosses, and the second LED chips on the second temporary substrate are bonded to the second bosses.

9. The method of claim 8, wherein the first bosses each have a height of H11, the second bosses each have a height of H22, and the following conditions are met: H22≥h3, H11≥H22+h2, H11=H31−H1, and H22=H31−H21.

10. The method of claim 6, wherein the first grooves are formed by exposure and development or by etching.

11. The method of claim 7, wherein the second grooves are formed by exposure and development or by etching.

12. A non-transitory computer readable storage medium storing a computer program which, when executed by a processor, causes the processor to:
provide a first growth substrate with first LED chips thereon, electrodes of the first LED chips facing away from the first growth substrate;
provide a first temporary substrate with an adhesive thereon, adhere the electrodes of the first LED chips to a first adhesive layer of the first temporary substrate, and peel off the first growth substrate;
coat, on the first temporary substrate with the first LED chips thereon, photosensitive resin to form a first photosensitive resin layer having a thickness of H1 greater than a height h1 of each of the first LED chips, i.e., H1>h1;
cover, on the first photosensitive resin layer, a second temporary substrate made of a light-transmitting material;
provide a patterned mask to block light towards first LED chips not to be transferred, and to expose a part of the first photosensitive resin layer corresponding to first LED chips to be transferred for solidification of the part of the first photosensitive resin layer, and remove an unexposed part of the first photosensitive resin layer with a developer, a remaining part of the first photosensitive resin layer serving as first transfer heads;
peel off, selectively from the first adhesive layer by laser peeling, the first LED chips to be transferred, so that the first LED chips to be transferred are adhered to the second temporary substrate via the first transfer heads; and
move the second temporary substrate to transfer the first LED chips on the second temporary substrate to a display backplane and dissolve the first transfer heads with a peeling liquid to separate the first LED chips from the second temporary substrate, to complete transfer of the first LED chips.

13. The non-transitory computer readable storage medium of claim 12, wherein the computer program, when executed by the processor, further causes the processor to:
provide a second growth substrate with second LED chips thereon, electrodes of the second LED chips facing away from the second growth substrate;
provide a third temporary substrate with an adhesive thereon, adhere the electrodes of the second LED chips to a second adhesive layer of the third temporary substrate, and peel off the second growth substrate;
coat, on the third temporary substrate with the second LED chips thereon, photosensitive resin to form a second photosensitive resin layer having a thickness of H2 greater than a height h2 of each of the second LED chips, i.e., H2>h2, wherein if the height h2 of each of the second LED chips is unequal to the height h1 of each of the first LED chips, the thickness H2 of the second photosensitive resin layer covering the second LED chips is preset to meet the following condition: H2−h2>|h2−h1|;
cover, on the second photosensitive resin layer, a fourth temporary substrate made of a light-transmitting material;
provide a patterned mask to block light towards second LED chips not to be transferred, and to expose a part of the second photosensitive resin layer corresponding to second LED chips to be transferred for solidification of the part of the second photosensitive resin layer, and remove an unexposed part of the second photosensitive resin layer with a developer, a remaining part of the second photosensitive resin layer serving as second transfer heads;
peel off, selectively from the second adhesive layer by laser peeling, the second LED chips to be transferred, so that the second LED chips to be transferred are adhered to the fourth temporary substrate via the second transfer heads; and
move the fourth temporary substrate to transfer the second LED chips on the fourth temporary substrate to the display backplane and dissolve the second transfer heads with a peeling liquid to separate the second LED chips from the fourth temporary substrate, to complete transfer of the second LED chips.

14. The non-transitory computer readable storage medium of claim 13, wherein the computer program, when executed by the processor, further causes the processor to:
provide a third growth substrate with third LED chips thereon, electrodes of the third LED chips facing away from the third growth substrate;
provide a fifth temporary substrate with an adhesive thereon, adhere the electrodes of the third LED chips to a third adhesive layer of the fifth temporary substrate, and peel off the third growth substrate;
coat, on the fifth temporary substrate with the third LED chips thereon, photosensitive resin to form a third photosensitive resin layer having a thickness of H3 greater than a height h3 of each of the third LED chips, i.e., H3>h3, wherein if the height h3 of each of the third LED chips, the height h2 of each of the second LED chips, and the height h1 of each of the first LED chips are unequal to each other, the thickness H3 of the third photosensitive resin layer covering the third LED chips is preset to meet the following conditions: H3−h3>|h3−h1| and H3−h3>|h3−h2|;
cover, on the third photosensitive resin layer, a sixth temporary substrate made of a light-transmitting material;
provide a patterned mask to block light towards third LED chips not to be transferred, and to expose a part of the third photosensitive resin layer corresponding to third LED chips to be transferred for solidification of the part of the third photosensitive resin layer, and remove an unexposed part of the third photosensitive resin layer with a developer, a remaining part of the third photosensitive resin layer serving as third transfer heads;
peel off, selectively from the third adhesive layer by laser peeling, the third LED chips to be transferred, so that the third LED chips to be transferred are adhered to the sixth temporary substrate via the third transfer heads; and
move the sixth temporary substrate to transfer the third LED chips on the sixth temporary substrate to the display backplane and dissolve the third transfer heads with a peeling liquid to separate the third LED chips from the sixth temporary substrate, to complete transfer of the third LED chips.

15. The non-transitory computer readable storage medium of claim 12, wherein the computer program, when executed by the processor, further causes the processor to:
provide a second growth substrate with second LED chips thereon, the second LED chips each having a height of h2;
provide a third temporary substrate with a second adhesive layer formed thereon, adhere the second LED chips to the third temporary substrate, remove the second growth substrate, and coat, on the third temporary substrate with the second LED chips thereon, photosensitive resin to form a second photosensitive resin layer having a thickness of H21 which meets H21≥H1;
form, on the second photosensitive resin layer, first grooves corresponding to the first LED chips, and cover, on the second photosensitive resin layer, the second temporary substrate with the first LED chips thereon;
provide a patterned mask to block light towards second LED chips not to be transferred, and to expose a part of the second photosensitive resin layer corresponding to second LED chips to be transferred for solidification of the part of the second photosensitive resin layer, and remove an unexposed part of the second photosensitive resin layer with a developer, a remaining part of the second photosensitive resin layer serving as second transfer heads; and
peel off, selectively from the second adhesive layer by laser peeling, the second LED chips to be transferred, so that the second LED chips to be transferred are adhered to the second temporary substrate via the second transfer heads.

16. The non-transitory computer readable storage medium of claim 15, wherein the computer program, when executed by the processor, further causes the processor to:
provide a third growth substrate with third LED chips thereon, the third LED chips each having a height of h3;
provide a fourth temporary substrate with a third adhesive layer formed thereon, adhere the third LED chips to the fourth temporary substrate, remove the third growth substrate, and coat, on the fourth temporary substrate with the third LED chips thereon, photosensitive resin to form a third photosensitive resin layer having a thickness of H31 which meets H31≥H2+h3;
form, on the third photosensitive resin layer, second grooves and third grooves corresponding to the first LED chips and the second LED chips, and cover, on the third photosensitive resin layer, the fourth temporary substrate with the first LED chips and the second LED chips thereon;
provide a patterned mask to block light towards third LED chips not to be transferred, and to expose a part of the third photosensitive resin layer corresponding to third LED chips to be transferred for solidification of the part of the third photosensitive resin layer, and remove an unexposed part of the third photosensitive resin layer with a developer, a remaining part of the third photosensitive resin layer serving as third transfer heads; and
peel off, selectively from the third adhesive layer by laser peeling, the third LED chips to be transferred, so that the third LED chips to be transferred are adhered to the second temporary substrate via the third transfer heads.

17. The non-transitory computer readable storage medium of claim 16, wherein the display backplane comprises first bosses and second bosses, the first LED chips on the second temporary substrate are bonded to the first bosses, and the second LED chips on the second temporary substrate are bonded to the second bosses.

18. The non-transitory computer readable storage medium of claim 17, wherein the first bosses each have a height of H11, the second bosses each have a height of H22, and the following conditions are met: H22≥h3, H11≥H22+h2, H11=H31−H1, and H22=H31−H21.

19. The non-transitory computer readable storage medium of claim 15, wherein the first grooves are formed by exposure and development or by etching.

20. The non-transitory computer readable storage medium of claim 16, wherein the second grooves are formed by exposure and development or by etching.
